(19) United States
(12) Patent Application Publication
(10) Pub. No.: US 2007/0211534 A1
(43) Pub. Date: Sep. 13, 2007

(54) METHOD FOR PROGRAMMING/ERASING A NON VOLATILE MEMORY CELL DEVICE

(75) Inventors: Angelo Visconti, Appiano Gentile (CO) (IT); Mauro Bonanomi, Cassano d'Adda (MI) (IT); Daniele Ielmini, Bergamo (IT); Alessandro Spinelli, Bergamo (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.r.l., Agrate Brianza (MI) (IT)

(21) Appl. No.: 11/684,052

(22) Filed: Mar. 9, 2007

(30) Foreign Application Priority Data
Mar. 10, 2006 (EP) 06425164.8

(51) Int. Cl. G11C 11/34; G11C 16/04; G11C 16/06

(52) U.S. Cl. 365/185.19; 365/185.18; 365/185.22

(57) ABSTRACT

The method for programming/erasing a non volatile memory cell device includes at least one electric stress step to apply, to at least one active oxide layer of at least one memory cell of the device, a stress electric field able to remove at least a part of charges trapped in the active oxide layer. The method may be used for devices with floating gate type memory cells. The electric stress step may include the application, to one or more terminals of at least one memory cell, of potentials able to produce an electric field on a corresponding active oxide layer.

### FIELD OF THE INVENTION

The present invention relates to programming and erasing in a non volatile memory cell device. The invention particularly, but not exclusively, relates to a non volatile memory device of the Flash NOR type and the following description is made with reference to this field of application to simplify its disclosure.

### BACKGROUND OF THE INVENTION

As it is known, the methods for programming/erasing non volatile memory electronic devices act on the charge contained in floating gate terminals of memory cells included in these devices. In particular, as schematically shown in FIG. 1A, a non volatile memory cell 1 includes a source region 2 and a drain region 3, formed in a semiconductor substrate 4 and provided with respective source S and drain D electrodes. Also the semiconductor substrate is provided with a substrate electrode B or bulk.

The memory cell 1 also includes a floating gate 7, formed above the semiconductor substrate 4, in particular above a channel region 5, and insulated therefrom by a tunnel oxide layer 6. A control gate 8 is also placed above the floating gate 7, separated therefrom by an insulating layer, and in turn connected to a gate electrode G.

In a non volatile memory device, for example memories of the EPROM and Flash EEPROM type with NOR architecture, the non volatile memory cells 1 are organized in a matrix and associated with a control circuitry comprising a plurality of MOS transistors. The operations of programming/erasing non volatile memory cells 1 provide the application of suitable voltage values to the cell terminals. FIG. 1A indicates these voltage values applied to the gate G, source S, drain D and substrate B terminals respectively as V_{G}, V_{S}, V_{D} and V_{B}.

In particular, the overcoming of suitable voltage values at the terminals of the memory cell 1, usually called “programming/erasing voltages”, starts the transfer of electrons and thus the passage of charge from the semiconductor substrate 4 to the floating gate 7 and vice versa, as indicated in the Figure by the arrows F1 and F2.

It is also known that the duration and reliability of non volatile memory devices thus formed may be linked to the accumulation of electric charge in the tunnel oxide layer 6 of the memory cells 1 comprised therein, this accumulation being linked to the repeated programming/erasing operations. In particular, the passage of electric current in the tunnel oxide layer 6 during these operations generates electronic states wherein the charge carriers may remain trapped, as schematically shown in FIG. 1B where 9 indicates the carriers or accumulated charges. This problem is described in the documents published in the name of N. Mielke et al, “Flash EEPROM Threshold Instabilities due to Charge Trapping during Program/Erase Cycling”, TDMR 2004 and in the name of Yamada et al., “Analysis of Detrap Current due to Oxide Traps to Improve Flash Memory Retention”, IRPS 2000.

A first effect of this charge accumulation may be that of making the writing operations of the memory cell 1 less efficient. In fact, it occurs that the cell programming and erasing threshold values become a function of the number of programming/erasing cycles. In particular, by repeatedly programming and erasing a memory cell 1 of the Flash type, with fixed time conditions and writing pulse voltage, a trend of these programming and erasing threshold values may be obtained according to the number of programming/erasing P/E cycles as the one schematically represented in FIG. 2A.

Then, so as to ensure, during the entire life of the memory device, predetermined threshold voltage levels, which correspond to determined logic levels stored in the memory cells, the programming/erasing methods provide an increase of times and/or voltages of the writing pulses to compensate the loss of efficiency of the writing itself. This however induces an increase in the programming/erasing times which, in the worse cases, can lead to an “off-specification”, i.e. to devices which no longer respect the design specifications and thus the limits of the applications for which they are intended.

A second problem due to the accumulation of charge in the oxide is the one linked to its successive release during the operation of the memory device. In particular, when a memory cell 1 is not in the writing step, the charge accumulated during the cycling of programming/erasing operations may tend to naturally relax and thus it is released by the traps towards the channel region 5 or the floating gate 7, according to the electric potentials applied to the terminals of the memory cell 1.

For example, considering a memory cell 1 in retention of a first logic value represented by a first threshold voltage Vth1 and established for the memory cell 1 after a writing step, the “natural” charge release can be high enough as to remarkably alter the electric field in the tunnel oxide layer 6, to which this charge contributes together with the charge present in the floating gate 7. In this case, at a successive reading step of the cell itself, a threshold voltage value Vth1′ is measured, the voltage being different from this first threshold voltage Vth1, thus leading to a possible reading error of the logic value stored in the memory cell 1.

FIG. 2B shows the threshold voltage Vth distributions experimentally obtained for memory cells belonging to a memory sector cycled after programming and after retention at 150° C. It is immediately observed that the above described phenomenon of “natural” charge release (sometimes referred to as “detrapping”) strongly depends on the temperature, since this facilitates the emission of the electric charges or carriers of the traps increasing the thermal energy, but it also depends on the electric field since this alters the form of the trap potential barrier also allowing the passage of the carriers assisted by the so called tunnel effect.

It is thus apparent why the “detrapping” phenomenon is dangerous mainly at high temperatures and is particularly sensitive on logic levels placed at thresholds corresponding to high electric fields in retention. This “detrapping” phenomenon is thus particularly critical for the multilevel devices, which can have a wider reading threshold window with respect to the one-level or single bit devices and which also have very fine threshold margins between the different logic levels stored therein.

It is well known that the release times of the electric charges accumulated in the tunnel oxide layer 6 can be very long (even years) at environment temperatures, while they are definitely reduced at higher temperatures. Flash memory devices currently on sale have retention specifications for a time equal to 10 years and operative temperatures up to 85-125° C. For a reliable operation of a memory device during its whole operative life it is thus necessary to suitably design it and in particular to reserve, in the threshold window, a suitable margin for ensuring the correct reading of the different logic levels also in the presence of possible shifts of the threshold voltage of the memory cells comprised therein. However, the resulting widening of the threshold window has the effect of worsening other reliability aspects of the memory device, linked to the general enhancement of the electric fields associated to the device itself.

The technical problem underlying the present invention is the need for programming/erasing a non volatile memory device so as to eliminate the degradation of the threshold value of the memory cells therein during the programming/erasing steps as well as the effects of trapping and releasing of electric charge inside the cells themselves, without limiting neither the speed of these programming/erasing steps nor the reliability of the device in general, so as to overcome the limits and the drawbacks still affecting the methods for programming/erasing non volatile memory devices realized according to the prior art.

### SUMMARY OF THE INVENTION

The approach of the present invention introduces, in a method for programming/erasing a memory device, at least one electric stress step suitable for applying, to the memory cells, an electric field able to remove at least a part of the electric charges trapped in the respective tunnel oxide layers. Accordingly, the technical problem described above is addressed by the described method.

### BRIEF DESCRIPTION OF THE DRAWINGS

The characteristics and advantages of the programming/erasing method according to the invention will be apparent from the following description of an embodiment thereof given by way of an indicative and non limiting example with reference to the drawings.

FIGS. 1A and 1B are schematic cross-sectional views illustrating a floating gate non volatile memory cell according to the prior art.

FIGS. 2A and 2B are graphs showing a trend of characteristic parameters of the cell of FIGS. 1A and 1B.

FIGS. 3A and 3B are timing diagrams schematically showing a trend of a threshold value of non volatile memory cells, in particular belonging to a same memory sector, during a programming step and an erasing step, respectively, according to the method of the present invention.

FIGS. 4A and 4B are charts showing the mean variation of a threshold voltage of memory cells programmed/erased according to the method of the present invention.

FIGS. 5A and 5B are timing diagrams schematically showing a trend of a threshold value of single-level non volatile memory cells, in particular belonging to a same memory sector, during a programming step and an erasing step, respectively, according to a method of the present invention;

FIGS. 6A and 6B are timing diagrams schematically showing a trend of a threshold value of two-level non volatile memory cells, in particular belonging to a same memory sector, during a programming step and an erasing step, respectively, according to a method of the present invention.

FIG. 7 is a graph showing experimental results of the method according to the invention applied to a Flash type memory device.

### DETAILED DESCRIPTION OF THE PREFERRED EMBODIMENTS

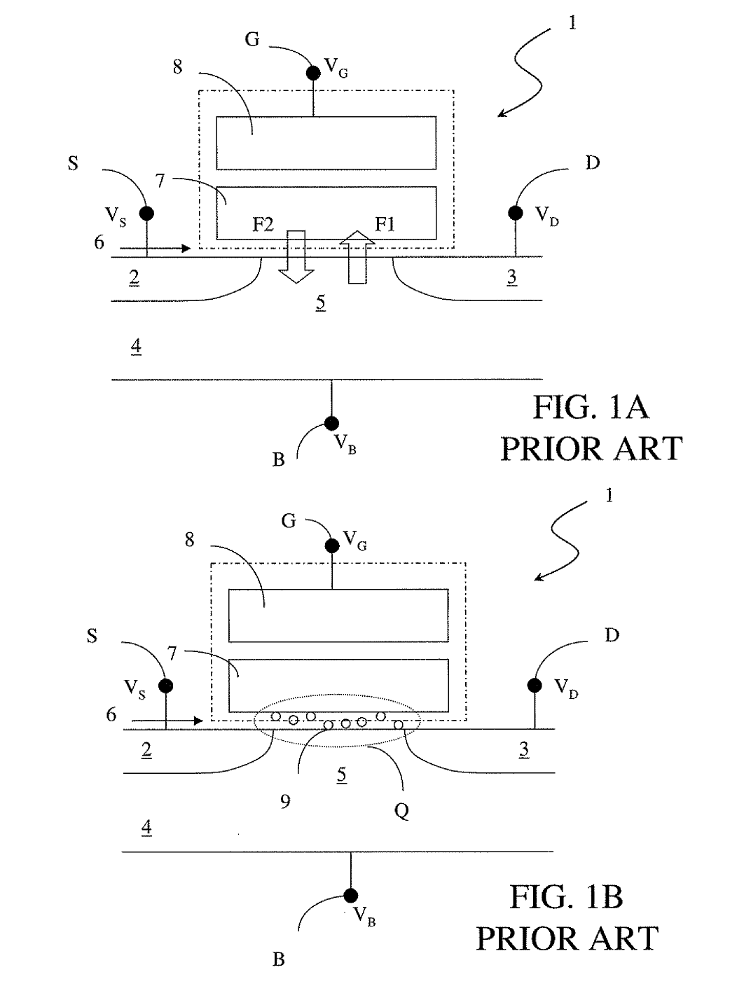

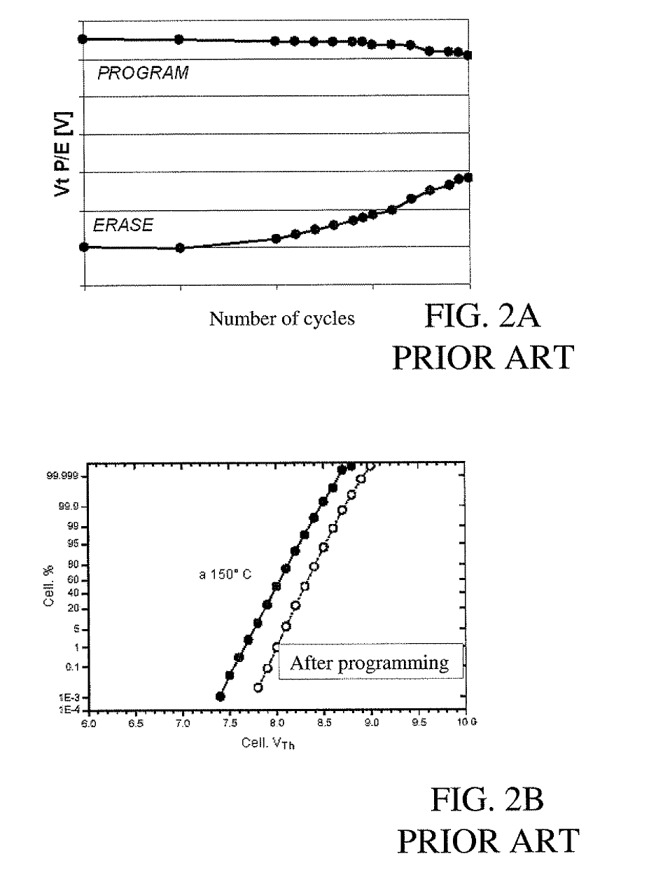

Advantageously according to the invention, a method is provided for programming/erasing a memory device including at least one electric stress step or phase for applying, to the memory cells, an electric field able to remove at least a part of the electric charges trapped in the respective tunnel oxide layers. The method may be used for devices with floating gate type memory cells as described, for example, in accordance with the prior art and shown in FIGS. 1A and 1B.

It is to be noted that the electric stress step includes the application, to one or more terminals of at least one memory cell 1, of potentials able to produce an electric field on a corresponding active oxide layer. The phrase “active oxide layer” indicates the cell layer crossed by a writing current and being a trapping sight of an amount Q of a charge, in particular the tunnel oxide layer 6 as previously described. In substance, the electric stress step thus may include a biasing step of at least one terminal of the memory cell 1 for generating a desired electric field in the active oxide layer. It is to be noted that, advantageously according to the invention, the electric field generated by the electric stress step in the active oxide layer should be enough to cause the release of at least a part of the amount Q of charge trapped in the active oxide layer, as indicated in particular in FIG. 1B.

In particular, to be efficient in releasing such part of amount 9 of trapped charge, the resulting electric field may be fixed so as to be high enough as to defeat the forces linking the charges 9 to the corresponding traps. Moreover, advantageously according to the invention, this resulting electric field may be fixed so as not to be so high as to generate a current which would cross the active oxide layer, in a way similar to the writing current of the memory cell 1. In this way, the resulting electric field does not cause a generation of new traps, with the consequent creation of an amount of charge even greater with respect to the release of the part of amount 9 of trapped charge, as it occurs during the writing operations.

To determine such a value for this resulting electric field as to meet the above indicated conditions and as to determine a condition of sole charge release from the already existing traps, the programming/erasing method according to the invention advantageously includes a step of testing a memory device which must be subjected to the programming/erasing operations. In particular, this test step comprises an experimental verification step of a group of memory cells, in particular a memory sector, under different stress conditions, corresponding to different values of the potentials applied to their terminals, subjected to a predetermined number of repeated writing operations, in turn comprising, in a known way, cyclings of programming/erasing operations to determine the desired electric field value to be applied during the electric stress step.

The experimental verify step may include the following: at the end of each one of the cyclings of programming/erasing operations, a test writing step during which all the memory cells of the group are written at a same threshold value Vt; and a retention test step accelerated by temperature, via which a measurement is carried out of a threshold variation of the group of cells occurred during a predetermined period when the memory device is left at a constant temperature value without carrying out further writing operations.

In particular, the test step may provide a reading of the group of cells prior to and after the application of an electric stress. In this way, the experimental verification step allows the best conditions to be obtained of the potentials applied to the terminals of the cells for a correct electric stress step, as those for which the threshold variation measured in the test step is at its minimum value.

Advantageously according to the invention, the experimental verification step also comprises a step of identifying a maximum value of the electric field applicable in the electric stress step, i.e. a maximum value of the potentials applicable to the terminals of the memory cell by the electric stress step to avoid a current generation similar to the writing current.

In particular, the identification step may include the following: application of a stress electric field on a non cycled cell for different values of this stress electric field; measurement of a variation of the cell threshold occurred between prior to and after the application of this stress electric field; and identification of a maximum value of this stress electric field corresponding to a significant variation of the cell threshold, in particular corresponding to a threshold variation of the cell when a writing operation is carried out with a non negligible writing current. Possibly, the identification step provides a repetition in sequence of the application of the stress electric field.

It is to be noted that the identification step of the highest value of the electric field applicable in the electric stress step allows identification of the electric field value which produces a current similar to a non negligible writing current, i.e. the critical condition wherein the application of the stress electric field could give a accurate balance of trap generation and thus of charge entrapped in the active oxide layer. This applied electric field is preferably between 2 MV/cm and 10 MV/cm.

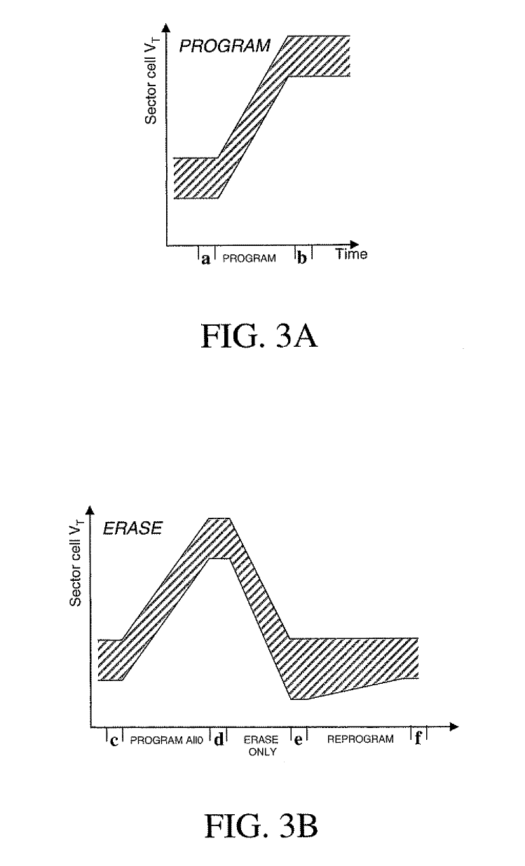

Advantageously according to the invention, the electric stress step is inserted in a typical programming/erasing method, in correspondence with writing operations of the memory cells of the device subjected to the programming/erasing operations, as schematically shown in FIGS. 3A and 3B for a programming and erasing operation, respectively, in the positions indicated with (a)-(f).

In particular, the electric stress step is inserted prior to and after the application of a programming pulse, indicated with program, i.e. in the positions (a) and (b) of FIG. 3A for a programming operation and in the positions (c) and (d) of FIG. 3B for an erasing operation. Moreover, this electric stress step is inserted prior to and after the application of a reprogramming pulse, indicated with reprogram, i.e. in the positions (e) and (f) of FIG. 3B for an erasing operation.

In general, the programming/erasing method according to the invention includes an electric stress step performed: during a programming operation at the beginning of this operation (point a) and/or at the end of the same (point b); and/or during an erasing operation at the beginning of this operation (point c), after an initial programming step (point d), after the real erasing step (point e), and after the reprogramming step (point f).

The electric stress step causes, in this way, at each writing cycle of the memory cells, a release of a part of the charge trapped in the active oxide layer 6, this charge entrapment being caused by the writing cycle itself and/or by preceding writing cycles. In this way, the method according to the invention allows to limit the charge accumulation in this active oxide layer and to reduce possible effects, including the charge release when a cell is in retention.

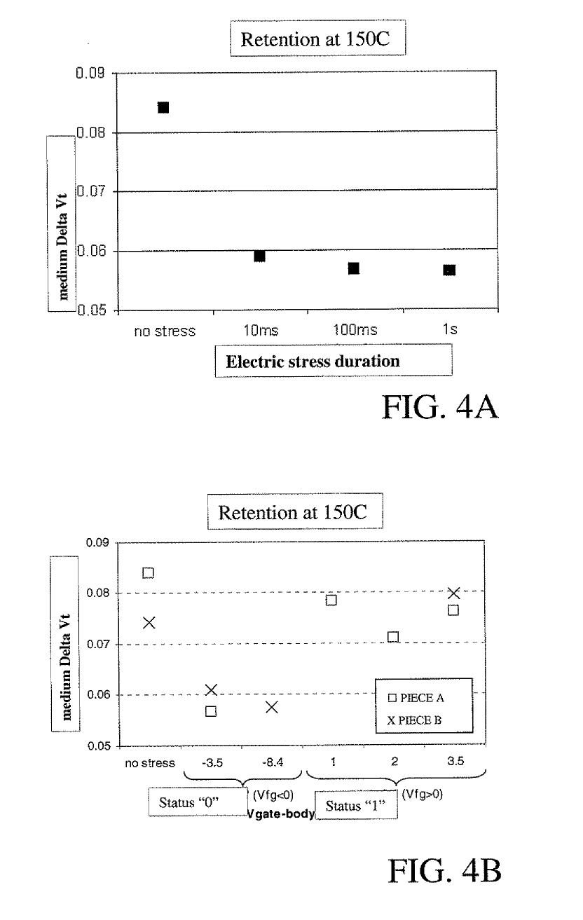

In a preferred embodiment of the method according to the invention, for using an application time of this electric stress step as long as possible (in the order of ms), the electric stress step is inserted during the erasing step. In particular, in the case of a memory device of the Flash NOR type, the electric stress step is inserted during the sector erasing step, whose duration is already of some hundreds of ms and thus is not prolonged a lot in percentage, as schematically shown in FIG. 4A.

It is to be noted that, in this case, the execution of the electric stress step in correspondence with the positions from (c) to (e) indicated in FIG. 3B for the erasing step, in parallel on all the cells of a sector in the case of a memory device of the Flash NOR type, is not dangerous for the disturbance of the logic data already written in these cells, since during the erasing step all and only the cells of the sector are re-written at the logic value “1” in a definitive way in the point indicated with (f) in FIG. 3B.

Moreover, in a preferred embodiment of the method according to the invention, the electric stress step is realized in parallel on all the cells, via application of a same stress potential to a given electrode of the cells, which may be identical for all the cells of the sector. It is also possible to realize the electric stress step in a sequential way, by applying a given stress potential in a sequential way on groups of different cells each time, for example by scanning the rows or the columns. In this case, however, an increase of the total time of the writing operation occurs.

In any case, it is possible to insert this electric stress step during the programming step, for example of one or more words, limiting the duration thereof, to remain within the normal times of execution of this programming step equal to some tens of μs. In this case, it is to be taken into account that the application of the stress potential during a programming operation of one or more words could create a disturbance on the data stored in the cells which are not involved in the writing operation interested in the electric stress step, also when this electric stress step was realized in a selective way on the sole cells interested in the writing operation.

It is however to be noted that the method according to the invention is generally applicable to memory devices of the Flash NOR or NAND type, but also to memories with nano-crystals, with discrete traps and with nitride, e.g. NROM. In general, the choice of the moment when the electric stress step is to be carried out depends on considerations regarding the control circuitry of the memory device considered, in combination with the choice of the most efficient electric potentials for the charge release from the traps.

It has been experimentally observed that an electric stress step with application of a stress potential for the Control Gate terminals being lower than the stress potentials of the body, source and drain terminals, maintained almost equi-potential, is efficient for an accurate charge release from the traps. It occurs that this release may be dependent on the electric field for voltage values between Control Gate and body terminals comprised between −3.5V and −8.4V provided on a cell in the programmed state, as shown in FIG. 4B.

Therefore, in a preferred embodiment of the method according to the invention, it follows that the electric stress step is realized just prior to the erasing step, i.e. in the position (d) of FIG. 3B. In fact, in this position, the pulses applied to the electrodes of the cell have similar duration and potentials with the same sign, but different width, thus facilitating the circuit implementation of the method. In particular, it is possible to apply a stress potential to the void body terminal and to the negative Control Gate terminal, but also a different distribution of the voltage between the two electrodes allows to obtain the desired charge release.

Advantageously, the electric stress step according to the invention comprises the application of a potential, i.e. the biasing, of the electrode of the gate, substrate or body, source or drain, these potentials being both positive and negative and this biasing involving more than one electrode simultaneously. Advantageously according to the invention, the electric stress step comprises the application of stress potentials via one or more pulses, rectangular or of other form (for example ramp-like), according to the specific circuit implementation.

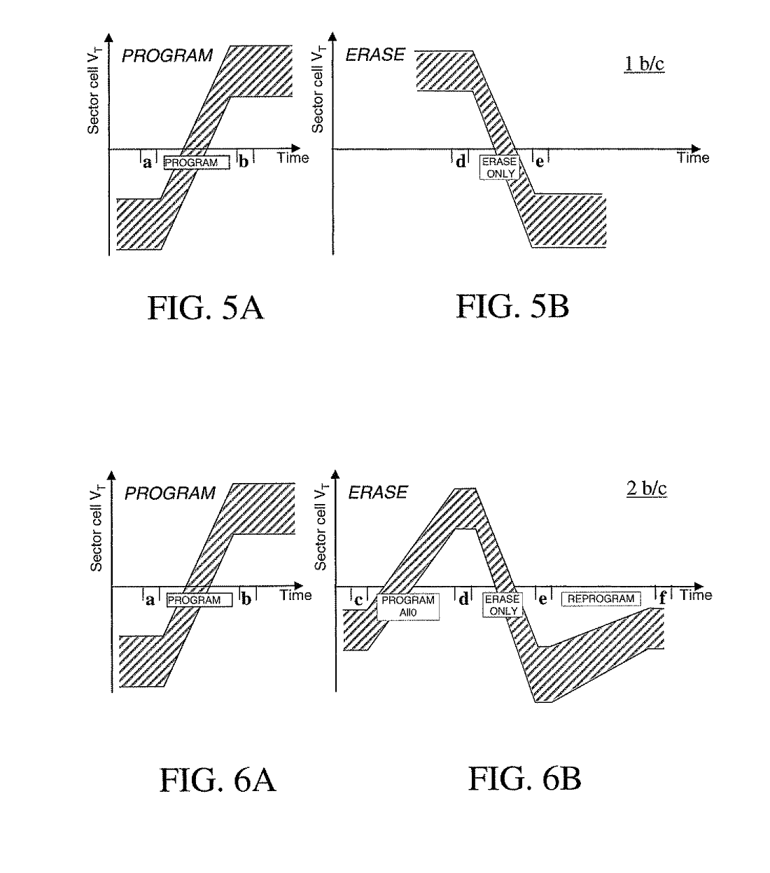

It is noted that the considerations made for the explanatory case of a memory device of the Flash NOR type are applicable in general. For example, in the case of a memory device of the Flash NAND type, it is however possible to insert the electric stress step according to the invention in any point of a programming/erasing method of the known type, as schematically shown in FIGS. 5A-5B and 6A-6B for the case of two-level (1 bit per cell) and multilevel (two bits per cell) devices, respectively.

Also in this case, since the duration of a programming operation can be of a few hundreds of μs for devices with 1 bit per cell up to almost 1 ms for devices with 2 bits per cell, it is possible to insert the electric stress step according to the invention in such a programming operation with duration in the order of the ten of μs, in particular in the points indicated with (a) and/or (b) in FIGS. 5A and 6A, preferring point (a) since in correspondence with this point the logic datum stored in the cells interested in the electric stress step has not been described yet. Also in this case a disturbance on other cells different from those interested in the writing operation may be inevitable.

Similarly, the insertion of the electric stress step during an erasing operation has the advantage of applying longer pulses, the duration of this operation being equal to a few ms. In particular, by inserting the electric stress step in the points indicated with (c), (d) and (e) the advantage is obtained of avoiding the generation of disturbances on a logic datum stored in the cells interested in the stress step, these having to be written in a definitive way only at point (f).

It is noted that the electric stress step is inserted in a normal method for programming/erasing a memory device, of the type already used in the sector and it is possible to implement it by using the normal control circuitry these devices are provided with. In particular, in the case shown of a memory device of the Flash NAND type, the control circuitry is normally realized for managing only positive voltages. It is however possible to apply stress potentials similar to those previously indicated for the devices of the Flash NOR type, i.e. with a negative voltage value between Control Gate and body terminals in the order of some Volt, by simply maintaining the potential of the Control Gate terminal to ground and enhancing the potential of the body terminal to a desired positive value.

Moreover, according to the needs of simplification of the control circuitry, also different distributions of the potentials onto the electrodes are possible for generating a same voltage or form of the pulses different from a simple rectangular pulse, as for example a ramp pulse or a sequence of more pulses can be contemplated.

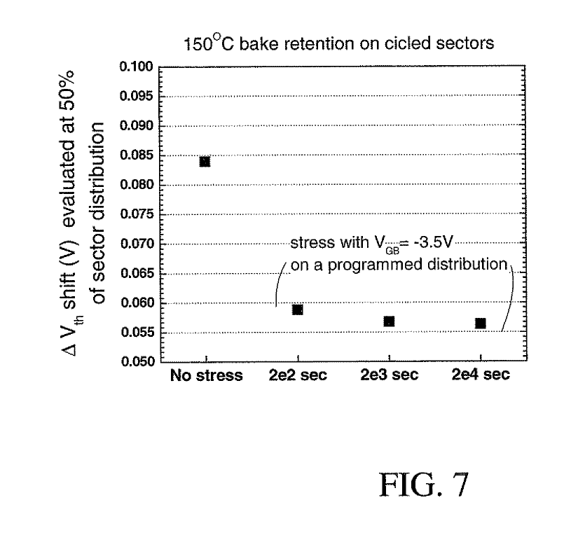

From experimental tests carried out by the Applicants, the beneficial effect has been observed of an electric stress step with voltage applied between body and gate on cycled sectors, with verification that the charge released during the retention test at 150° C. after cycling of 20 k cycles is remarkably reduced for a sector whereon the electric stress step according to the invention has been applied, with respect to a sector without applied stresses as schematically shown in FIG. 7.

In particular, a 50% threshold shift of the sector cells has been measured for a sector non subjected to the electric stress step and for other sectors subjected to the electric stress step according to the invention with increasing times. This threshold shift is in fact due to the charge released by the traps and is proportional, with identical electric field conditions, times and temperatures, to the trapped charge itself. It has thus been verified how it is possible to use electric stress steps of short duration, however efficient for the charge release, and which do not excessively prolong the writing time of the data in the memory device, this being a parameter to be maintained as low as possible.

In conclusion, the programming/erasing method according to the invention allows the reduction of the effects of threshold variation of the memory cells interested in the programming/erasing steps during the retention steps of the same, to moderate the increase in the programming/erasing times of the memory device comprising these cells, and, simultaneously, to avoid other reliability problems due to the accumulation of charge trapped in the tunnel oxide layers of the cells.

1-29. (canceled)

30. A method for operating a non volatile memory device including a plurality of memory cells each having at least one active oxide layer, the method comprising:
programming at least one memory cell;
erasing the at least one memory cell; and
applying, to the at least one active oxide layer of the at least one memory cell of the non volatile memory device, an electric field to remove at least a part of electric charges trapped in the at least one active oxide layer and defining at least one electric stress phase.

31. The method according to claim 30, wherein the at least one memory cell includes at least one terminal; and wherein the at least one electric stress phase comprises applying an electric stress potential to the at least one terminal of the at least one memory cell.

32. The method according to claim 30, wherein the at least one electric stress phase provides the electric field at a value sufficient to defeat forces linking electric charges to respective traps in the active oxide layer.

33. The method according to claim 32, wherein the electric stress phase provides the electric field with at a lower value than an electric field value for generating a current in the active oxide layer.

34. The method according to claim 31, further comprising testing the memory device including at least one verification phase of a group of memory cells of the memory device for different values of potentials applied to terminals thereof when subjected to a predetermined number of repeated writing operations including programming/erasing cycles.

35. The method according to claim 34, wherein the verification phase comprises:
at an end of each one of the programming/erasing cycles, a test writing phase during which the memory cells of the group are written at a same threshold value; and
a retention test phase accelerated by temperature, via which a measurement is carried out of a threshold variation of the group of memory cells occurring during a period when the memory device is left at a temperature constant value without carrying out subsequent writing operations.

36. The method according to claim 35, wherein said testing comprises a reading of the group of memory cells prior to and after the electric stress phase.

37. The method according to claim 34, wherein the verification phase establishes optimal stress electric field conditions in correspondence with the threshold variation measured in the testing at a minimum value.

38. The method according to claim 34, wherein the verification phase further comprises an identification phase to identify a maximum value of the electric field based upon an absence of a current in the at least one active oxide layer.

39. The method according to claim 38, wherein the identification phase comprises:
applying the electric field to a non cycled memory cell for different values of the electric stress potential;
measuring a threshold variation of the memory cell occurring from prior to and after applying the electric field; and
identifying a maximum value of the electric field based upon a variation of the measured threshold.

40. The method according to claim 39, wherein the identification phase further comprises repeating application of the electric field.

41. The method according to claim 30, wherein the electric stress phase is performed based upon a writing operation of the memory cells of the memory device.

42. The method according to claim 41, wherein the electric stress phase is performed prior to the programming operation.

43. The method according to claim 41, wherein the electric stress phase is performed after the programming operation.

44. The method according to claim 41, wherein the electric stress phase is performed prior to the erasing operation.

45. The method according to claim 41, wherein the erasing operation includes an initial programming phase; and wherein the electric stress phase is performed after the initial programming step of the erasing operation.

46. The method according to claim 41, wherein the electric stress phase is performed after an erasing phase of the erasing operation.

47. The method according to claim 41, wherein the electric stress phase is performed after a reprogramming phase of the erasing operation.

48. The method according to claim 41, wherein the electric stress phase comprises applying the electric field for a duration corresponding to a duration of the writing operation.

49. The method according to claim 41, wherein the electric stress phase comprises applying the electric field in parallel on a plurality of memory cells of the memory device.

50. The method according to claim 41, wherein the electric stress phase comprises applying the electric field sequentially on groups of different memory cells of the memory device.

51. The method according to claim 31, wherein applying the electric stress potential to at least one terminal of the memory cell comprises a biasing phase to bias the at least one terminal of the memory cell between at least one of a control gate, a body, a source and a drain.

52. The method according to claim 51, wherein applying the electric stress potential includes positive and negative potentials.

53. The method according to claim 51, wherein applying the electric stress potential includes applying the electric stress potential to more than one terminal of the memory cell simultaneously.

54. The method according to claim 51, wherein applying the electric stress potential comprises applying the electric stress potential to a control gate terminal lower than a stress potential of body, source and drain terminals, maintained substantially equi-potential.

55. The method according to claim 31, wherein the electric stress phase comprises applying the stress potential via at least one rectangular pulse.

56. The method according to claim 31, wherein the electric stress phase comprises applying the stress potential via at least one ramp pulse.

57. The method according to claim 30, wherein the electric stress phase is performed on a group of memory cells.

58. The method according to claim 57, wherein the group of memory cells corresponds to a sector of the memory device.
